(19) United States
(12) Patent Application Publication
(10) Pub. No.: US 2021/0073438 A1
(43) Pub. Date: Mar. 11, 2021

(54) OPTIMIZATION SYSTEM, OPTIMIZATION METHOD, CONTROL CIRCUIT AND COMPUTER READABLE STORAGE MEDIUM

(71) Applicant: Mitsubishi Electric Corporation, Tokyo (JP)

(72) Inventor: Yuji AKIYAMA, Tokyo (JP)

(73) Assignee: Mitsubishi Electric Corporation, Tokyo (JP)

(21) Appl. No.: 16/952,645

(22) Filed: Nov. 19, 2020

Related U.S. Application Data
(63) Continuation of application No. PCT/JP2018/021611, filed on Jun. 5, 2018.

(51) Int. Cl. G06F 30/20; G06F 11/07

(52) U.S. Cl. CPC G06F 30/20; G06F 11/076; G06F 11/0745

(57) ABSTRACT

An optimization system for optimizing a parameter using simulated annealing includes: a condition setting unit that sets conditions including a temperature to be used, a parameter candidate to be evaluated, and a measurement time that is a time for measuring an evaluation value of a cost function for evaluating the parameter candidate; an evaluation unit that measures the evaluation value using the conditions; an acceptance determination unit that determines whether to accept the parameter candidate based on the evaluation value; and a termination determination unit that determines whether a predetermined termination condition is satisfied. An evaluation process including setting of the conditions, measurement of the evaluation value, and acceptance determination for the parameter candidate is repeated until the termination condition is satisfied. The condition setting unit determines the measurement time based on the temperature used in the evaluation process each time the evaluation process is repeated.

### CROSS-REFERENCE TO RELATED APPLICATION

This application is a continuation application of International Application PCT/JP2018/021611, filed on Jun. 5, 2018, and designating the U.S., the entire contents of which are incorporated herein by reference.

### BACKGROUND OF THE INVENTION

### 1. Field of the Invention

The present disclosure relates to an optimization system and an optimization method using simulated annealing.

### 2. Description of the Related Art

Methods for optimizing a system having multiple parameters are called combinatorial optimization problems. Examples of solution methods for combinatorial optimization problems that achieve faster convergence, include gradient descent such as the method of steepest descent. However, gradient descent has a serious drawback: it is highly likely to converge to a local optimum that depends on a search initial value.

To address this drawback, Non Patent Literature 1 discloses an optimization method using simulated annealing. Simulated annealing is a technique for optimizing a combination of multiple parameters by repeating an evaluation process that selects a parameter candidate from a parameter space, evaluates the selected parameter candidate, and determines whether to accept the parameter based on the evaluation value. In simulated annealing, the probability distribution for selecting parameter candidates is broadened initially so that a broad region of the parameter space can be searched, and the search range is gradually narrowed toward a low-energy region. This can reduce the probability of convergence to a local optimum that depends on a search initial value. In simulated annealing, a parameter called “temperature” is used to control the search range. The temperature is a real number of zero or more. As the temperature increases, the search range becomes wider.

### CITATION LIST

### Non Patent Literature

Non Patent Literature 1: S. Kirkpatrick, C. D. Gelatt Jr., M. P. Vecchi, Optimization by Simulated Annealing, Science, New Series, Vol. 220, No. 4598. (May 13, 1983), pp. 671-680.

However, the optimization method using simulated annealing disclosed in Non Patent Literature 1 above is problematic in that the optimization takes time.

The present disclosure has been made in view of the above, and an object thereof is to obtain an optimization system capable of shortening the time required for optimization.

### SUMMARY OF THE INVENTION

An optimization system according to the present disclosure for optimizing a parameter using simulated annealing includes: a condition setting unit to set conditions including a temperature to be used, a parameter candidate that is a parameter to be evaluated, and a measurement time that is a time for measuring an evaluation value of a cost function for evaluating the parameter candidate; an evaluation unit to measure the evaluation value using the conditions set; an acceptance determination unit to determine whether to accept the parameter candidate based on the evaluation value; and a termination determination unit to determine whether a predetermined termination condition is satisfied, wherein an evaluation process including setting of the conditions, measurement of the evaluation value, and acceptance determination for the parameter candidate is repeated until the termination condition is satisfied, and the condition setting unit determines the measurement time based on the temperature used in the evaluation process each time the evaluation process is repeated.

### BRIEF DESCRIPTION OF THE DRAWINGS

FIG. 1 is a diagram illustrating a configuration of an optimization system according to a first embodiment.

FIG. 2 is a diagram illustrating the relationship between a parameter to be optimized by the optimization system illustrated in FIG. 1 and the evaluation value of a cost function.

FIG. 3 is a diagram illustrating the relationship between the temperature and the measurement time used by the optimization system illustrated in FIG. 1.

FIG. 4 is a flowchart illustrating the operation of the optimization system illustrated in FIG. 1.

FIG. 5 is a flowchart illustrating the operation of an optimization system according to a second embodiment.

FIG. 6 is a diagram illustrating the relationship between elapsed time and signal-to-noise ratio in the optimization process of the optimization system according to the second embodiment.

FIG. 7 is a diagram illustrating the relationship between the number of steps and signal-to-noise ratio in the optimization process of the optimization system according to the second embodiment.

FIG. 8 is a diagram illustrating a configuration of an optimization system according to a third embodiment.

FIG. 9 is a diagram illustrating a configuration of an optimization system according to a fourth embodiment.

FIG. 10 is a diagram illustrating processing circuitry according to the first to fourth embodiments.

FIG. 11 is a diagram illustrating a control circuit according to the first to fourth embodiments.

FIG. 12 is a diagram illustrating a modification of the optimization system illustrated in FIG. 1.

FIG. 13 is a diagram illustrating a modification of the optimization system illustrated in FIG. 8.

### DETAILED DESCRIPTION OF THE PREFERRED EMBODIMENTS

Hereinafter, an optimization system and an optimization method according to embodiments of the present disclosure will be described in detail with reference to the drawings.

### First Embodiment

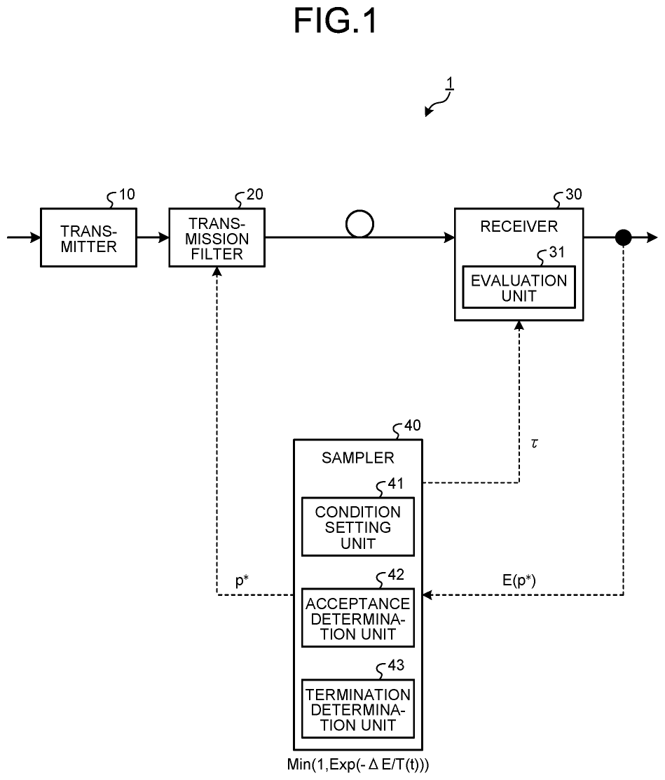

FIG. 1 is a diagram illustrating a configuration of an optimization system 1 according to the first embodiment. The optimization system 1 includes a transmitter 10, a transmission filter 20, a receiver 30, and a sampler 40.

The optimization system 1 optimizes, using simulated annealing, parameters used in a communication path for transmitting a signal from the transmitter 10 to the receiver 30 via the transmission filter 20. Here, parameters to be optimized are, for example, adjustment parameters for the communication path, and may include the filter coefficient of the transmission filter 20. The optimization system 1 repeatedly performs an evaluation process that selects a parameter candidate p* based on a temperature T that changes according to a temperature schedule, measures an evaluation value E(p*) for the parameter candidate p* selected, and determines whether to accept the parameter candidate p* based on the evaluation value E(p*). The evaluation process is repeated multiple times until a termination condition is satisfied. The temperature T indicates the probability distribution of the gradient descent rate, in other words, indicates the breadth of the distribution of the probability that the parameter candidate p* is accepted as a sample point in the search space. By gradually lowering the temperature T, the breadth of the distribution of the probability that the parameter candidate p* is accepted as a sample point in the search space, is gradually narrowed and converges to the optimum solution. The configuration for implementing this operation will be described below.

The transmitter 10 generates a transmission signal sequence from transmission information. The transmitter 10 inputs the generated transmission signal sequence to the transmission filter 20. The transmission filter 20 filters and shapes the input transmission signal sequence. The transmission filter 20 outputs the shaped transmission signal sequence to the communication path connected to the receiver 30. The transmission filter 20 is, for example, a finite impulse response (FIR) filter. The transmitter 10 filters the transmission signal sequence using the parameter candidate p* set by the sampler 40 described later.

The receiver 30 receives the transmission signal sequence transmitted from the transmitter 10 via the transmission filter 20 and the communication path. The receiver 30 generates reception information based on the received transmission signal sequence. The receiver 30 includes an evaluation unit 31. The evaluation unit 31 measures the evaluation value E(p*) using a measurement time T. As described above, the optimization process including the measurement of the evaluation value E(p*) is repeatedly performed, and conditions are set each time the optimization process is repeated. The evaluation unit 31 is implemented by, for example, an error detection circuit provided in the receiver 30. The evaluation unit 31 measures the evaluation value E(p*) of the cost function over the measurement time τ set by the sampler 40. The receiver 30 outputs the generated reception information and the measured evaluation value E(p*). The evaluation value E(p*) output by the receiver 30 is input to the sampler 40.

The sampler 40 is a device that samples the parameter candidate p* from a target parameter space, and is also a control device that controls the execution of an optimization method using simulated annealing. The sampler 40 includes a condition setting unit 41, an acceptance determination unit 42, and a termination determination unit 43. The condition setting unit 41 sets conditions for the evaluation process. Conditions for the evaluation process include the temperature T, the parameter candidate p*, and the measurement time T. The condition setting unit 41 determines the temperature T used in the evaluation process according to a predetermined temperature schedule, for example. For the temperature schedule, for example, the condition setting unit 41 can set the temperature T used in the current evaluation process based on a current time t or current step t. Then, the condition setting unit 41 selects, based on the currently accepted parameter p(t) from the search range specified by the determined temperature T, the parameter candidate p* that is a candidate for the next parameter p(t+1). The condition setting unit 41 can also determine the measurement time τ, which is the time for measuring the evaluation value E(p*) for the selected parameter candidate p*, based on the temperature T. The condition setting unit 41 notifies the transmission filter 20 of the selected parameter candidate p* and notifies the receiver 30 of the determined measurement time τ.

The acceptance determination unit 42 uses the conditions set by the condition setting unit 41 to determine whether to accept the parameter candidate p* based on the evaluation value E(p*) of the cost function measured during the transmission of the signal from the transmitter 10 to the receiver 30. In response to determining to accept the parameter candidate p*, the acceptance determination unit 42 sets the parameter candidate p* as the parameter p(t+1). The acceptance determination unit 42 notifies the condition setting unit 41 of the determination result. The termination determination unit 43 determines whether to finish repeating the optimization process using a predetermined termination condition. The termination condition is, for example, that the elapsed time from the start of the optimization process or the number of repetitions of the evaluation process reaches a predetermined threshold value. The termination determination unit 43 notifies the condition setting unit 41 of the determination result.

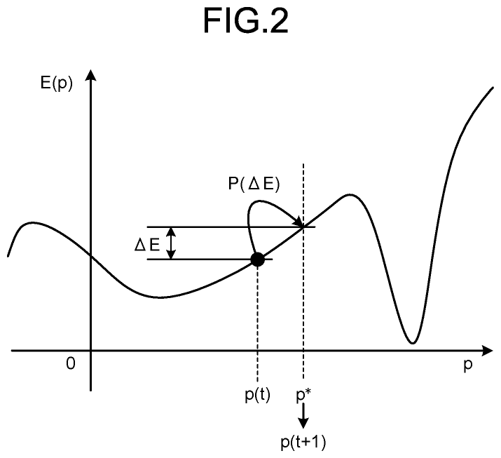

FIG. 2 is a diagram illustrating the relationship between the parameter p to be optimized by the optimization system 1 illustrated in FIG. 1 and the evaluation value E(p) of the cost function. The parameter p is a target of the optimization process of the optimization system 1. The parameter p is schematically represented in one dimension in FIG. 2, but is generally a value specified in a multidimensional space composed of a plurality of axes. The evaluation value E(p) is a scalar value. The parameter p(t) is the value of the accepted parameter p for the current time t or step t. The parameter candidate p* is a candidate for a parameter to be accepted, and is a parameter value sampled by the condition setting unit 41 from the vicinity of the current parameter p(t). When the acceptance determination unit 42 determines to accept the parameter candidate p*, the parameter candidate p* becomes the parameter p(t+1) for the next time t+1 or step t+1.

The parameter transition probability P(ΔE), which is the probability of transition from the parameter p(t) to the parameter p(t+1), is determined depending on the difference ΔE between the evaluation value E(p) of the cost function for the parameter p(t) and the evaluation value E(p) of the cost function for the parameter p(t+1), and on the temperature T.

In simulated annealing, the parameter transition probability P(ΔE) for the case in which the difference value of the cost function associated with the transition in the parameter space is the difference ΔE, is represented by Formula (1) below, where T is a real number of zero or more indicating the temperature at the time of transition.

$$\begin{matrix}[ Formula 1 ] & \\ P ( Δ E ) = min ( 1 , {e}^{- \frac{Δ E}{T}} ) & ( 1 )\end{matrix}$$

As a result, it is possible to satisfy the detailed balance condition in stochastic sampling with the Metropolis-Hastings algorithm, which is a method used by simulated annealing for sampling. When the temperature change is sufficiently slow, the parameter space has a Boltzmann distribution in which the probability distribution is exponentially determined with respect to the evaluation value E(p) of the cost function. Therefore, by gradually lowering the temperature T from a high temperature to a low temperature, the probability distribution in the parameter space exponentially concentrates in the part where the evaluation value E(p*) of the cost function is low, which, combined with the fact that the probability distribution is flat at high temperatures in the initial stage of optimization, can efficiently cause the probability distribution to converge to the global optimum value, not to a local optimum.

In simulated annealing, it is desirable that the temperature schedule can be freely adjusted because the accuracy of optimization changes by appropriately controlling the temperature in each stage of optimization. Therefore, it is undesirable that restrictions be imposed on the applicability of temperature schedules for any reason unrelated to the accuracy of optimization. In the present embodiment, any temperature schedule is applicable.

In a case where an average bit error rate (BER) in the desired measurement time τ is used as the evaluation value E(p) of the cost function, the measurement noise increases as the measurement time τ decreases. The parameter transition probability P_{τ}(ΔE) in which the effect of the measurement time τ is considered is represented by Formula (2) below, where k is a constant indicating the degree of effect of the measurement time τ in the measurement system.

$$\begin{matrix}[ Formula 2 ] & \\ {P}_{τ} = ( Δ E ) = \frac{1}{\sqrt{π k τ}} {\int }_{- ∞}^{∞} {e}^{- k {α}^{2}} P ( Δ E - ɛ ) d ɛ & ( 2 )\end{matrix}$$

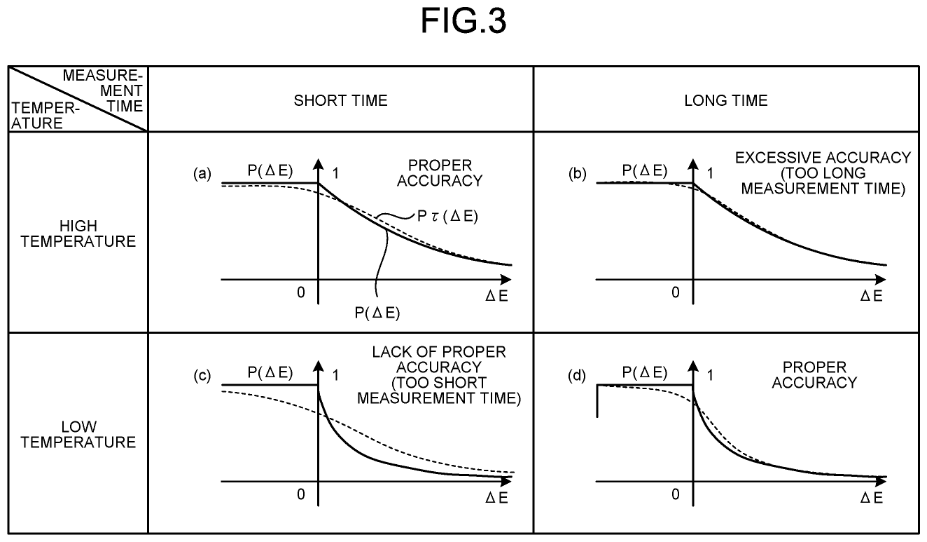

FIG. 3 is a diagram illustrating the relationship between the temperature T and the measurement time τ used by the optimization system 1 illustrated in FIG. 1. As described above, simulated annealing uses stochastic sampling with the Metropolis-Hastings algorithm, and the Metropolis-Hastings algorithm controls the probability distribution in the parameter space using the parameter transition probability P_{τ}(ΔE). Therefore, the effect of shortening the measurement time τ on the parameter transition probability P_{τ}(ΔE) increases as the temperature T becomes lower, and the accuracy of optimization can increase as the measurement time τ becomes longer. On the other hand, the effect of the measurement time τ on the parameter transition probability P_{τ}(ΔE) becomes relatively small as the temperature T becomes higher. In particular, if the measurement time τ is constant, it is necessary to perform long-time measurements in all evaluation processes, resulting in excessive accuracy and unnecessarily long measurement times τ for high temperatures T.

Therefore, the condition setting unit 41 can determine the measurement time τ based on the temperature T. More specifically, the condition setting unit 41 can shorten the measurement time τ as the temperature T becomes higher. For example, the condition setting unit 41 can determine the measurement time τ such that the measurement time τ has a value proportional to a function that monotonically decreases as the temperature T becomes higher. As a more specific example, the condition setting unit 41 can determine the measurement time τ such that the measurement time τ has a value proportional to the reciprocal of the square root of the temperature, according to Formula (3) below.

$$\begin{matrix}[ Formula 3 ] & \\ τ ( t ) ∝ \frac{1}{\sqrt{T ( t )}} & ( 3 )\end{matrix}$$

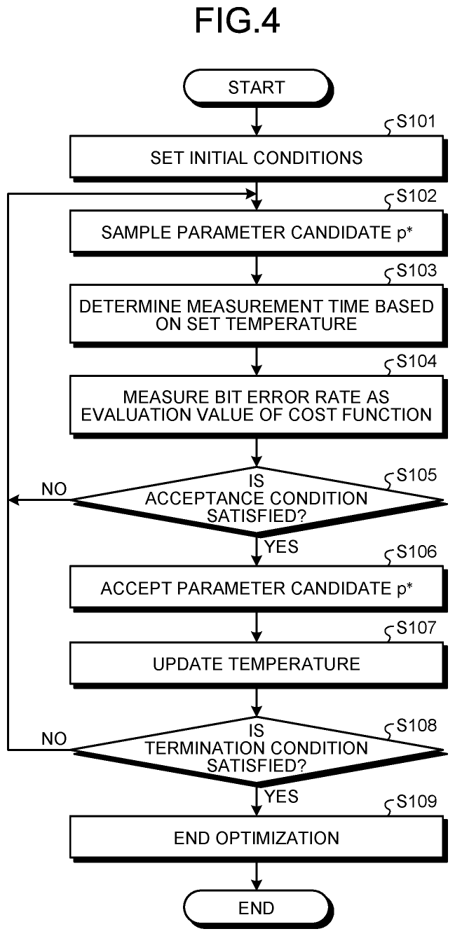

FIG. 4 is a flowchart illustrating the operation of the optimization system 1 illustrated in FIG. 1. First, the condition setting unit 41 of the sampler 40 sets initial conditions (step S101). Initial conditions include the temperature T and the parameter p. The condition setting unit 41 samples the parameter candidate p* based on the accepted parameter p and the set temperature T (step S102). Specifically, the condition setting unit 41 samples the parameter candidate p* in the vicinity of the accepted parameter p from the search range indicated by the set temperature T. The condition setting unit 41 notifies the transmission filter 20 of the sampled parameter candidate p*.

The condition setting unit 41 further determines the measurement time τ based on the set temperature T (step S103). Specifically, the condition setting unit 41 determines the measurement time τ such that the measurement time τ has a value proportional to the reciprocal of the square root of the temperature T used when sampling the parameter candidate p*, and notifies the receiver 30 of the determined measurement time T.

The evaluation unit 31 measures the bit error rate as the evaluation value E(p*) of the cost function using the reception signal received by the receiver 30 from the transmitter 10 via the transmission filter 20 (step S104). At this time, the evaluation unit 31 measures the evaluation value E(p*) over the set measurement time T. The evaluation unit 31 notifies the sampler 40 of the measured evaluation value E(p*).

The acceptance determination unit 42 of the sampler 40 determines whether the parameter candidate p satisfies the acceptance condition based on the evaluation value E(p*) provided by the evaluation unit 31 (step S105). When the acceptance condition is not satisfied (step S105: No), the acceptance determination unit 42 notifies the condition setting unit 41 that the acceptance condition is not satisfied, and returns to step S102 to repeat the process. When the acceptance condition is satisfied (step S105: Yes), the acceptance determination unit 42 accepts the parameter candidate p* (step S106). The acceptance determination unit 42 notifies the condition setting unit 41 that the acceptance condition is satisfied.

In response to being notified that the acceptance condition is satisfied, the condition setting unit 41 updates the temperature T according to the temperature schedule (step S107). The updated temperature T is used in the next evaluation process.

Then, the termination determination unit 43 determines whether the termination condition is satisfied (step S108). For example, in a case where the termination condition is to reach a predetermined total optimization time, the termination determination unit 43 can count the elapsed time from the start of the optimization process and determine whether the termination condition is satisfied based on whether the elapsed time has reached the predetermined total optimization time.

When the termination condition is satisfied (step S108: Yes), the sampler 40 ends the optimization (step S109). When the termination condition is not satisfied (step S108: No), the sampler 40 returns to step S102 to repeat the process.

As described above, according to the first embodiment, the optimization system 1 for optimizing the parameter p using simulated annealing includes: the condition setting unit 41 that sets conditions including the parameter candidate p* that is the parameter p to be evaluated and the measurement time τ that is the time for measuring the evaluation value E(p*) of the cost function for evaluating the parameter candidate p*; the evaluation unit 31 that measures the evaluation value E(p*) using the conditions set; the acceptance determination unit 42 that determines whether to accept the parameter candidate p* based on the evaluation value E(p*); and the termination determination unit 43 that determines whether a predetermined termination condition is satisfied. The optimization system 1 repeats the evaluation process including setting of the conditions, measurement of the evaluation value E(p*), and acceptance determination for the parameter candidate p* until the termination condition is satisfied.

Here, in each evaluation process, the condition setting unit 41 determines the measurement time τ for each evaluation value E(p*) based on the temperature indicating the range from which the parameter candidate p* is selected. Specifically, the condition setting unit 41 can determine the measurement time τ such that the measurement time τ is shortened as the temperature T used in the evaluation process becomes higher, and such that the measurement time τ has a value proportional to a function that monotonically decreases as the temperature T becomes higher. The function used in determining the measurement time τ can be the reciprocal of the square root of the temperature T, in which case the measurement time τ has a value proportional to the reciprocal of the square root of the temperature T. By determining the measurement time τ for each evaluation process in this way, the measurement time τ necessary for performing the evaluation process with the required accuracy can be appropriately determined, and unnecessary long-term measurement of evaluation values can be avoided. Thus, the time required for optimization can be shortened.

### Second Embodiment

Next, the second embodiment of the present disclosure will be described. In the first embodiment described above, the bit error rate of received data is used as the evaluation value E(p*) of the cost function. The second embodiment is different from the first embodiment in that signal-to-noise ratio is used. Hereinafter, differences from the first embodiment will be mainly described.

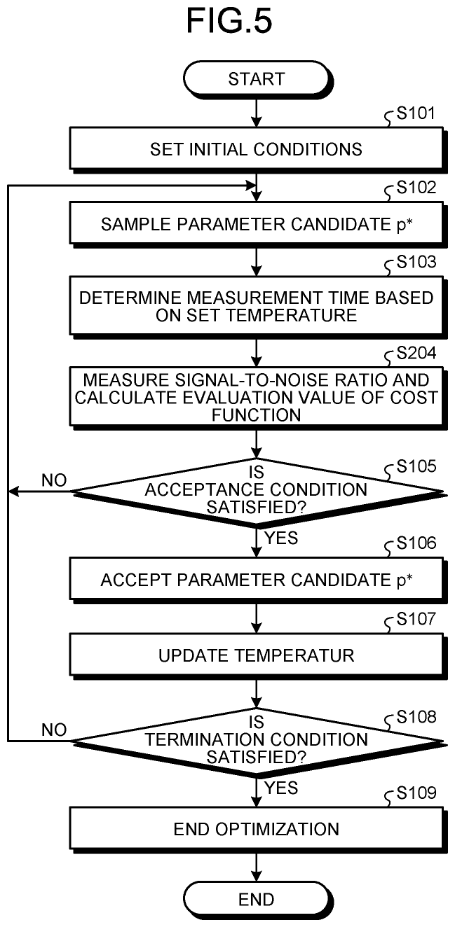

Because the configuration of an optimization system 2 according to the second embodiment is the same as that of the optimization system 1 illustrated in FIG. 1, the description thereof is omitted here. FIG. 5 is a flowchart illustrating the operation of the optimization system 2 according to the second embodiment.

Because steps S101 to S103 are the same as those in FIG. 4, the description thereof is omitted. The evaluation unit 31 measures the signal-to-noise ratio and calculates the evaluation value E(p*) of the cost function (step S204). Because steps S105 to S109 are the same as those in FIG. 4, the description thereof is omitted.

Here, an average signal-to-noise ratio in the measurement time τ is used as the evaluation value E(p*). Whereas the bit error rate used in the first embodiment indicates better characteristics at smaller values, the signal-to-noise ratio indicates better characteristics at larger values. Therefore, the signal-to-noise ratio can be used as the evaluation value E(p*) of the cost function, with its sign inverted. As the signal-to-noise ratio, either logarithmic ratio (dB) or linear ratio may be used.

In the above description, the evaluation value E(p*) based on the signal-to-noise ratio is adjusted such that smaller evaluation values E(p*) indicate better characteristics, which is a non-limiting example. Alternatively, the acceptance condition for step S105 may be adjusted. For example, if the acceptance condition for the case of using the bit error rate as the evaluation value E(p*) is that the evaluation value E(p*) is equal to or less than a threshold value, the acceptance condition for the case of using the signal-to-noise ratio as the evaluation value E(p*) is that the evaluation value E(p*) is equal to or larger than a threshold value.

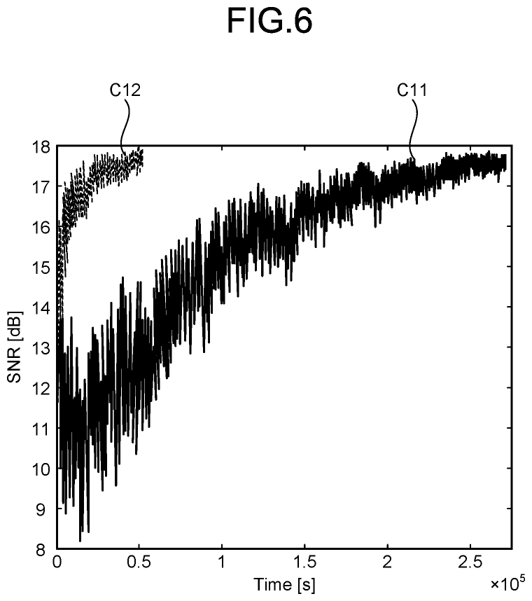

Next, the effect of the second embodiment will be described. FIG. 6 is a diagram illustrating the relationship between elapsed time and signal-to-noise ratio in the optimization process of the optimization system 2 according to the second embodiment. FIG. 6 depicts both a conventional optimization curve C11 that is based on a general simulated annealing method and an optimization curve C12 obtained by the optimization system 2. FIG. 6 illustrates that, compared with the case of using the general simulated annealing method, the optimization system 2 according to the second embodiment can rapidly advance characteristic improvement from the beginning to the middle of the optimization process to achieve optimization convergence in about ⅕ of the total time for the general simulated annealing method.

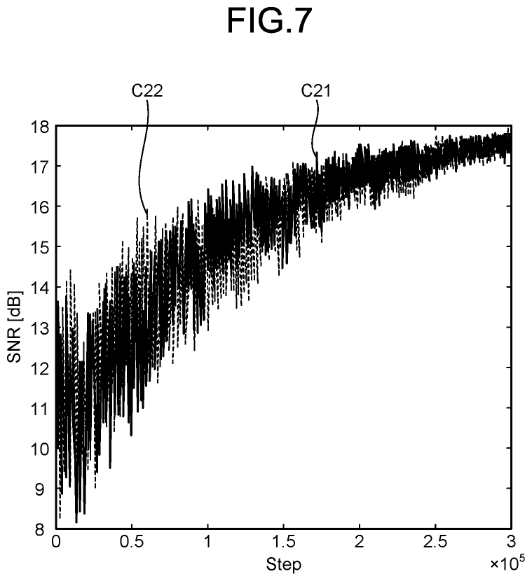

FIG. 7 is a diagram illustrating the relationship between the number of steps and signal-to-noise ratio in the optimization process of the optimization system 2 according to the second embodiment. FIG. 7 depicts both a conventional optimization curve C21 that is based on a general simulated annealing method and an optimization curve C22 obtained by the optimization system 2. FIG. 7 illustrates that although the optimization system 2 reduces the measurement time τ per step, no characteristic deterioration is observed even in comparison with the case of using the general simulated annealing method.

As described above, in the second embodiment, even in the case where the signal-to-noise ratio is used as the evaluation value E(p*), the time required for the optimization process can be shortened by determining the measurement time τ based on the temperature T.

### Third Embodiment

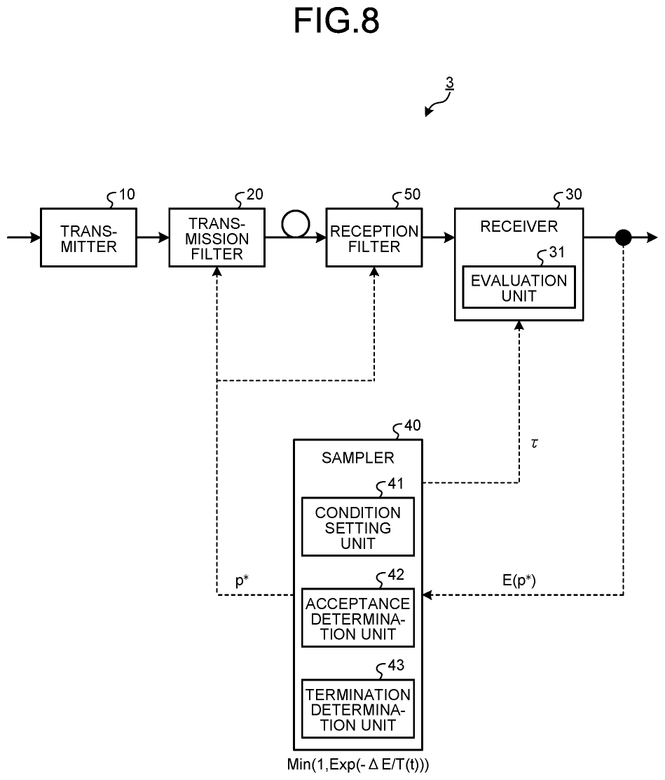

FIG. 8 is a diagram illustrating a configuration of an optimization system 3 according to the third embodiment. The optimization system 3 includes a reception filter 50 in addition to the components of the optimization systems 1 and 2. The reception filter 50 is, for example, an FIR filter, and is placed on the communication path through which a signal transmitted from the transmitter 10 via the transmission filter 20 is received by the receiver 30. As a result, the receiver 30 receives the signal filtered by the reception filter 50. Hereinafter, differences from the first and second embodiments will be mainly described.

The parameter candidate p* determined by the condition setting unit 41 of the sampler 40 is input to the reception filter 50 in addition to the transmission filter 20. The operation of the optimization system 3 is the same as that in the first and second embodiments except that parameters to be optimized include adjustment parameters for the reception filter, and therefore the description thereof is omitted here. Note that the evaluation unit 31 may use the bit error rate or signal-to-noise ratio as the evaluation value E(p*), depending on the configuration of the receiver 30.

As described above, the optimization system 3 according to the third embodiment can optimize not only adjustment parameters for the transmission filter 20 but also adjustment parameters for the reception filter 50.

### Fourth Embodiment

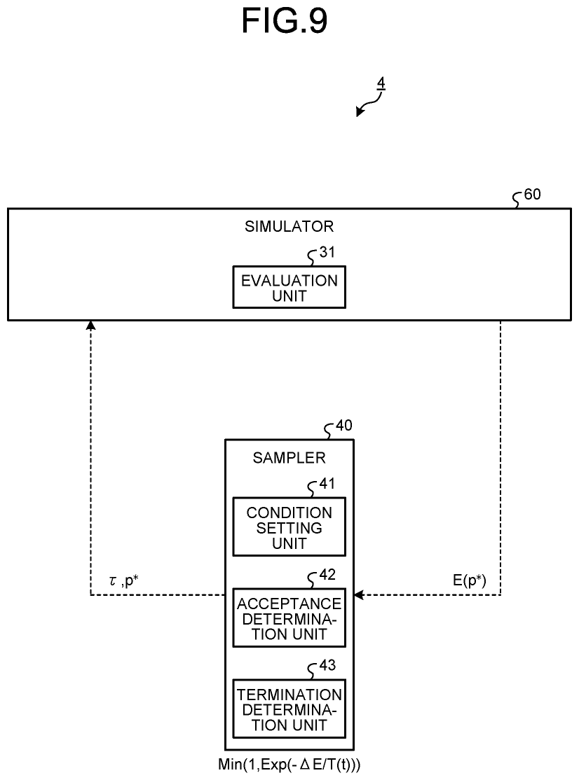

FIG. 9 is a diagram illustrating a configuration of an optimization system 4 according to the fourth embodiment. In the first to third embodiments, the evaluation value E(p*) of the cost function is obtained using a physical communication path or the like, which may be replaced with a computer simulation.

The optimization system 4 includes a simulator 60 and the sampler 40. The configuration of the sampler 40 is the same as that in the first to third embodiments. The measurement time τ and the parameter candidate p* set by the condition setting unit 41 of the sampler 40 are input to the simulator 60.

The simulator 60 includes the evaluation unit 31. The simulator 60 also has a function of simulating data transmission on a wireless communication path using conditions set by the sampler 40, e.g. the measurement time τ and the parameter candidate p*. In a typical simulation of a noisy system with the simulator 60, the evaluation value of the cost function is likely to vary depending on the measurement time τ. Therefore, by determining the measurement time τ based on the temperature T in the same way as in the evaluation of the characteristics of a physical communication path, the time required for the optimization process can be shortened.

Next, a hardware configuration of the first to fourth embodiments will be described. Each of the evaluation unit 31, the condition setting unit 41, the acceptance determination unit 42, and the termination determination unit 43 is implemented by processing circuitry. Processing circuitry may be implemented by dedicated hardware or may be a control circuit using a central processing unit (CPU).

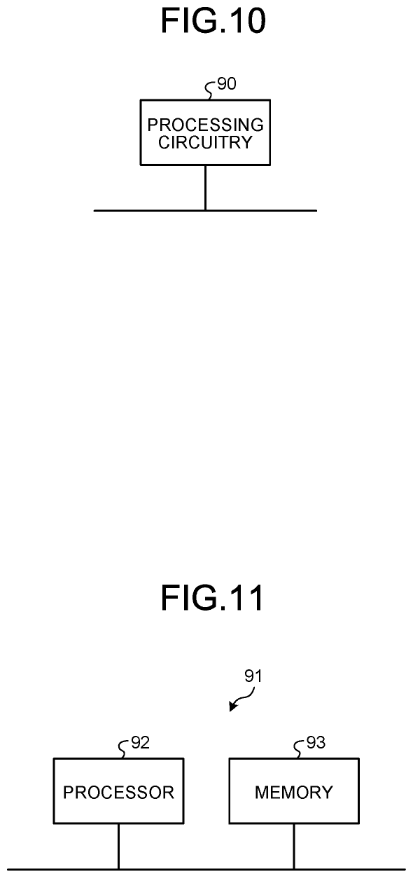

In a case where the above processing circuitry is implemented by dedicated hardware, the processing circuitry is implemented by processing circuitry 90 illustrated in FIG. 10. FIG. 10 is a diagram illustrating the processing circuitry 90 according to the first to fourth embodiments. The processing circuitry 90 is a single circuit, a composite circuit, a programmed processor, a parallel programmed processor, an application specific integrated circuit (ASIC), a field programmable gate array (FPGA), or a combination thereof.

In a case where the above processing circuitry is implemented by a control circuit using a CPU, this control circuit is, for example, a control circuit 91 having the configuration illustrated in FIG. 11. FIG. 11 is a diagram illustrating the control circuit 91 according to the first to fourth embodiments. As illustrated in FIG. 11, the control circuit 91 includes a processor 92 and a memory 93. The processor 92 is a CPU, and is also called a central processing device, a processing device, an arithmetic device, a microprocessor, a microcomputer, a digital signal processor (DSP), or the like. Examples of the memory 93 include a non-volatile or volatile semiconductor memory, a magnetic disk, a flexible disk, an optical disc, a compact disc, a mini disc, a digital versatile disc (DVD), and the like. Examples of non-volatile or volatile semiconductor memories include a random access memory (RAM), a read only memory (ROM), a flash memory, an erasable programmable ROM (EPROM), an electrically EPROM (EEPROM, registered trademark), and the like.

In a case where the above processing circuitry is implemented by the control circuit 91, the processor 92 reads and executes the program corresponding to the process of each component stored in the memory 93, thereby implementing the processing circuitry. The memory 93 is also used as a temporary memory for each process executed by the processor 92.

The configurations described in the above-mentioned embodiments indicate examples. The configurations can be combined with another well-known technique, and some of the configurations can be omitted or changed in a range not departing from the gist of the present disclosure.

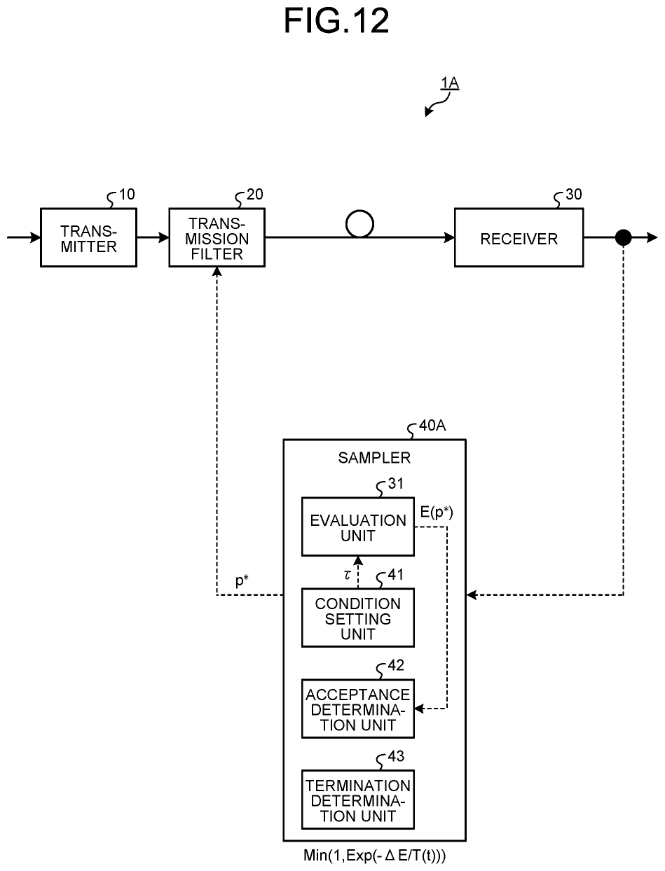

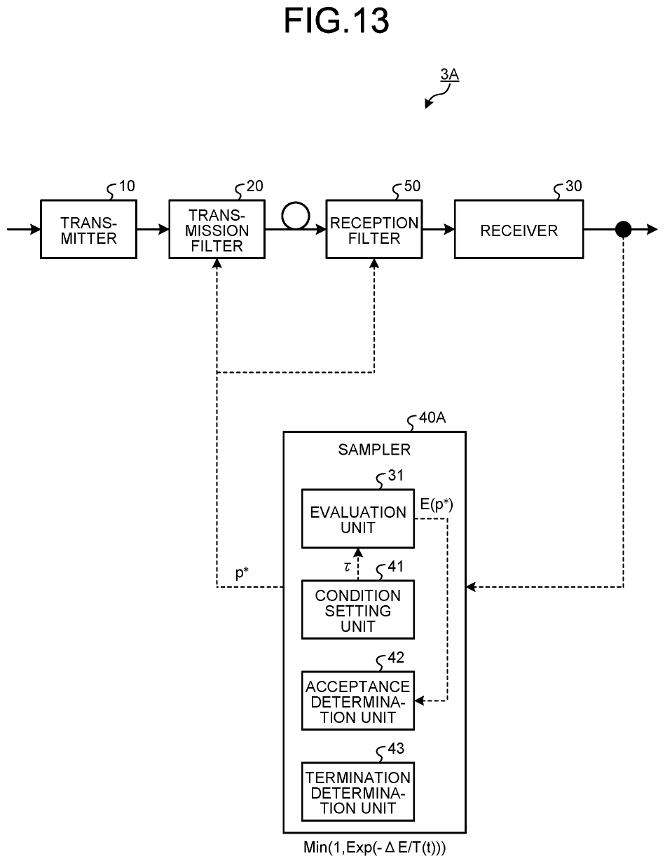

For example, in the above-described first to third embodiments, the receiver 30 includes the evaluation unit 31, but the present embodiments are not limited to this example. As illustrated in FIGS. 12 and 13, the evaluation unit 31 may be provided in a sampler 40A. FIG. 12 is a diagram illustrating a modification of the optimization system 1 illustrated in FIG. 1. FIG. 13 is a diagram illustrating a modification of the optimization system 3 illustrated in FIG. 8. The optimization system lA illustrated in FIG. 12 includes the sampler 40A including the evaluation unit 31, instead of the sampler 40 of the optimization system 1. Similarly, the optimization system 3A illustrated in FIG. 13 includes the sampler 40A including the evaluation unit 31, instead of the sampler 40 of the optimization system 3. In these cases, the receiver 30 does not include the evaluation unit 31 and inputs reception information to the sampler 40A. The condition setting unit 41 inputs the measurement time τ to the evaluation unit 31 inside the sampler 40A, and the evaluation unit 31 inputs the evaluation value E(p*) to the acceptance determination unit 42 inside the sampler 40A. By providing the evaluation unit 31 in the sampler 40A, the technique of the present embodiment can be implemented even with the receiver 30 that does not have the function of setting the measurement time T.

In the above-described embodiments, the transmission filter 20 and the reception filter 50 are FIR filters, but the present embodiments are not limited to this example. The transmission filter 20 and the reception filter 50 may be infinite impulse response (IIR) filters, e.g. non-linear filters such as Volterra filters. In the above-described embodiments, the parameter p to be optimized is the filter coefficient of the communication path, but the present embodiments are not limited to this example. For example, the parameter p may be an adjustment parameter for the communication path other than the filter coefficient, such as the transmission power, the temperature of the transmission device, and the modulation frequency. In addition, the communication path may be a multiplex of multiple transceivers.

In the above-described embodiments, the signal-to-noise ratio is used as the evaluation value E(p*) with its sign inverted, or the bit error rate is used as the evaluation value E(p*), but the present embodiments are not limited to this example. A value that is calculated based on the signal-to-noise ratio or bit error rate can also be used as the evaluation value E(p*). Alternatively, in a case where the parameter to be optimized is an adjustment parameter for the communication path, the evaluation value E(p*) may be any value that indicates the state of the communication path.

Furthermore, in the above-described embodiments, the parameter to be optimized is an adjustment parameter for the communication path, but the present embodiments are not limited to this example. In addition to the communication path, the technique of the present disclosure can be applied to any case where noise occurs in the characteristic evaluation of a system having a plurality of adjustment parameters, whereby similar effects can be obtained.

The optimization system according to the present disclosure can achieve the effect of shortening the time required for optimization.

Although the above-described embodiments disclose the configuration and operation of the optimization systems 1, 2, 3, and 4, the technique of the present disclosure can also be implemented in other forms such as an optimization method that is executed by the optimization system 1, 2, 3, or 4, an optimization program for executing the procedure of the optimization method, and a storage medium that stores the optimization program.

What is claimed is:

1. An optimization system for optimizing a parameter using simulated annealing, the optimization system comprising:
processing circuitry
to set conditions including a temperature to be used, a parameter candidate that is a parameter to be evaluated, and a measurement time that is a time for measuring an evaluation value of a cost function for evaluating the parameter candidate;
to measure the evaluation value using the conditions set;
to determine whether to accept the parameter candidate based on the evaluation value; and
to determine whether a predetermined termination condition is satisfied, wherein
an evaluation process including setting of the conditions, measurement of the evaluation value, and acceptance determination for the parameter candidate is repeated until the termination condition is satisfied, and
the processing circuitry determines the measurement time based on the temperature used in the evaluation process each time the evaluation process is repeated.

2. The optimization system according to claim 1, wherein the processing circuitry determines the measurement time such that the measurement time is shortened as the temperature used in the evaluation process becomes higher.

3. The optimization system according to claim 2, wherein the processing circuitry determines the measurement time such that the measurement time has a value proportional to a function that monotonically decreases as the temperature used in the evaluation process becomes higher.

4. The optimization system according to claim 3, wherein the processing circuitry determines the measurement time such that the measurement time has a value proportional to a reciprocal of a square root of the temperature used in the evaluation process.

5. The optimization system according to claim 1, wherein the parameter to be optimized is an adjustment parameter for a communication path.

6. The optimization system according to claim 5, wherein the adjustment parameter includes a filter coefficient of the communication path.

7. The optimization system according to claim 5, wherein the processing circuitry measures a bit error rate of data transmitted via the communication path, and calculates the evaluation value based on an average bit error rate in the measurement time.

8. The optimization system according to claim 5, wherein the processing circuitry measures a signal-to-noise ratio of data transmitted via the communication path, and calculates the evaluation value based on an average signal-to-noise ratio in the measurement time.

9. The optimization system according to claim 1, wherein the termination condition is that an elapsed time from a start of an optimization process or the number of repetitions of the evaluation process reaches a predetermined threshold value.

10. The optimization system according to claim 1, wherein functionality of the evaluating of measuring the evaluation value is implemented by a simulation using a computer.

11. An optimization method using simulated annealing for optimizing a parameter by repeatedly performing an evaluation process that selects a parameter candidate based on a temperature that changes according to a temperature schedule that decreases over time, measures an evaluation value of a cost function for the parameter candidate selected, and determines whether to accept the parameter candidate based on the evaluation value, wherein
each time the evaluation process is repeated, a measurement time for measuring the evaluation value for the parameter candidate is determined based on the temperature used for selecting the parameter candidate to be evaluated.

12. A control circuit to cause a control device to perform an optimization method using simulated annealing for optimizing a parameter by repeatedly performing an evaluation process that selects a parameter candidate based on a temperature that changes according to a temperature schedule that decreases over time, measures an evaluation value of a cost function for the parameter candidate selected, and determines whether to accept the parameter candidate based on the evaluation value, wherein
in the optimization method, each time the evaluation process is repeated, a measurement time for measuring the evaluation value for the parameter candidate is determined based on the temperature used for selecting the parameter candidate to be evaluated.

13. A non-transitory computer readable storage medium to store a program for controlling a control device, the program causes the control device
to perform an optimization method using simulated annealing for optimizing a parameter by repeatedly performing an evaluation process that selects a parameter candidate based on a temperature that changes according to a temperature schedule that decreases over time, measures an evaluation value of a cost function for the parameter candidate selected, and determines whether to accept the parameter candidate based on the evaluation value, wherein
in the optimization method, each time the evaluation process is repeated, a measurement time for measuring the evaluation value for the parameter candidate is determined based on the temperature used for selecting the parameter candidate to be evaluated.
